(19) United States
(12) Patent Application Publication
(10) Pub. No.: US 2009/0053620 A1
(43) Pub. Date: Feb. 26, 2009

(54) Blank Mask and Method for Fabricating Photomask Using the Same

(75) Inventor: Tae Joong Ha, Cheongju-si (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-si (KR)

(21) Appl. No.: 11/961,327

(22) Filed: Dec. 20, 2007

(30) Foreign Application Priority Data
Aug. 24, 2007 (KR) 10-2007-0085478

(51) Int. Cl. G03F 1/00

(52) U.S. Cl. 430/5

(57) ABSTRACT

A photomask is formed on an etch target layer of a transparent substrate using a blank mask that includes a carbon layer and an oxide layer. The carbon layer and the oxide layer are disposed on the etch target layer. The oxide layer is formed into an oxide layer pattern by photolithography for selectively exposing the etch target layer. A carbon layer pattern is formed by etching the carbon layer using the oxide layer pattern. An etch target layer pattern is formed by etching the etch target layer using the carbon layer pattern as a hard mask. Therefore, a sufficient thickness of the carbon layer can be etched using a thin oxide layer pattern employing the etch selectivity characteristics of the oxide layer and the carbon layer. Furthermore, the etch target layer pattern can have a predetermined vertical profile. The carbon layer pattern can be removed using oxygen plasma without damaging the underlying etch target layer pattern.

### CROSS REFERENCE TO RELATED APPLICATION

Priority to Korean patent application No. 10-2007-0085478 filed on Aug. 24, 2007, the disclosure of which is incorporated by reference in its entirety, is claimed.

### BACKGROUND OF THE INVENTION

1. Field of the Disclosure

The disclosure generally relates to a semiconductor device and a method for fabricating the device, and more particularly, to a blank mask and a method for fabricating a photomask using the blank mask.

2. Brief Description of Related Technology

Semiconductor devices are fabricated through a number of processes. For example, in a process for fabricating a semiconductor device, a photomask having a circuit pattern is used to form a circuit layer pattern on a semiconductor substrate (e.g., a wafer). The circuit pattern is transferred from the photomask to a circuit layer of the semiconductor substrate (a wafer) by photolithography.

To form a photomask, an etch target layer and a resist layer are formed on a transparent substrate. A target pattern is transferred to the resist layer and is developed to form a resist pattern on the etch target layer that selectively exposes the etch target layer. The target layer is selectively etched using the resist pattern as an etch mask to form an etch target layer pattern.

As semiconductor devices become more highly integrated, photomasks having much finer patterns are required. An underlying target layer can be patterned according to the pattern of a resist layer pattern through an etch process using the resist layer pattern as an etch mask. In this case, the thickness of the resist layer pattern is associated with the thickness of the underlying target layer. In other words, when the underlying target layer is thin, the resist layer pattern also is thin. Consequently, when the resist layer pattern is thin, the process margin of a subsequent etch process can be decreased and, thus, the characteristics of a photomask can deteriorate. For example, when a target layer is etched using a thin resist layer pattern, the thin resist layer pattern can be almost removed during the etching of the target layer because the resist layer pattern is not durable, due to its thin thickness. In this case, the resist layer pattern can be partially lost (broken) and, thus, undesired portions of the underlying layer can be exposed to an etching agent. As a result, a desired pattern is not easily formed in the underlying target pattern, and particularly, it becomes very difficult to form a pattern having a predetermined vertical profile in the underlying target layer. On the other hand, when a thick resist layer is used for patterning an underlying target layer, the resolution of a pattern formed in an underlying target layer is low. In other words, it is difficult to form a fine pattern in an underlying target layer using a thick resist layer.

### SUMMARY OF THE INVENTION

Disclosed herein are a blank mask for a binary mask, a blank mask for a phase shift mask, and a method of fabricating a photomask employing the disclosed blank masks. In one embodiment, a photomask is fabricated using a blank mask that includes an etch target layer, a carbon layer, and a resist layer. The photomask is fabricated by forming an etch target layer and a carbon layer on a transparent substrate. A carbon layer pattern is formed by selectively etching the carbon layer through a first etch process, using a resist layer pattern that selectively exposes the carbon layer. An etch target layer pattern is formed by etching the etch target layer through a second etch process, using the carbon layer pattern as a hard mask; and the carbon layer pattern is thereafter removed.

The etch target layer may include a light blocking layer. Alternatively, the etch target layer may include a light blocking layer and a phase shift layer. The method of fabricating the photomask may further include forming an oxide layer on the carbon layer. The first etch process may be a dry etch process using oxygen plasma, for example. The second etch process may be a dry or wet etch process. The carbon layer pattern may be removed using oxygen plasma, for example.

Additional features of the invention may become apparent to those skilled in the art from a review of the following detailed description, taken in conjunction with the drawings, the examples, and the appended claims.

### BRIEF DESCRIPTION OF THE DRAWINGS

For a more complete understanding of the disclosure, reference should be made to the following detailed description and accompanying drawing wherein:

FIGS. 1 to 5 illustrate a blank mask and a method for fabricating a photomask using the blank mask according to an embodiment of the present invention; and,

FIGS. 6 to 12 illustrate a blank mask and a method for fabricating a photomask using the blank mask according to another embodiment of the present invention.

While the disclosed invention is susceptible of embodiments in various forms, there are illustrated in the drawing (and will hereafter be described) specific embodiments of the invention, with the understanding that the disclosure is intended to be illustrative, and is not intended to limit the invention to the specific embodiments described and illustrated herein.

### DESCRIPTION OF SPECIFIC EMBODIMENTS

Hereinafter, a blank mask and a method for fabricating a photomask using the blank mask in accordance with the present invention will be described in detail with reference to the accompanying drawings, wherein like reference numbers refer to the identical or similar elements in the various figures.

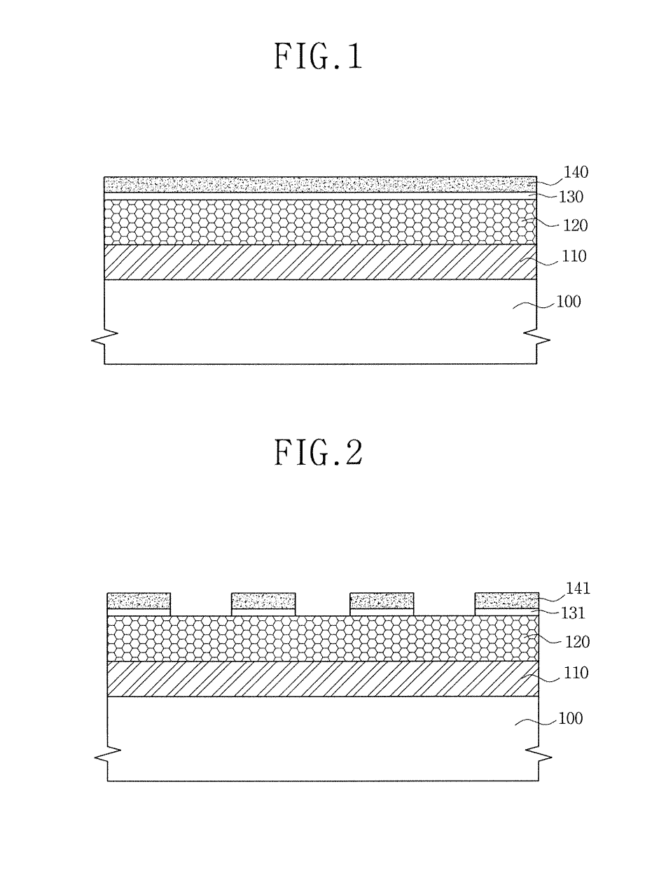

Referring to FIG. 1, an embodiment of a blank mask for a binary mask includes a light blocking layer 110, a carbon layer 120, and a resist layer 140 are disposed on a transparent substrate 100, such as a quartz substrate. The light blocking layer 110 preferably comprises a material, such as chromium (Cr), that can block incident light. An oxide layer 130 can be disposed between the carbon layer 120 and the resist layer 140. For example, the carbon layer 120 can be formed of amorphous carbon.

To fabricate a blank mask for a binary mask, the light blocking layer 110, the carbon layer 120, and the resist layer 140 are formed on the transparent substrate 100. As stated above, the light blocking layer 110 can be formed of a material, such as chromium, that can block incident light, and the oxide layer 130 can be formed between the carbon layer 120 and the resist layer 140.

As stated above, the carbon layer 120 can be formed of amorphous carbon. The carbon layer 120 can be formed using a compound including carbon as a reaction source. More specifically, after the transparent substrate 100 with the light blocking layer 110 formed thereon is loaded into a reaction chamber, a reaction source containing carbon can be supplied to the reaction chamber while applying a voltage to the reaction chamber suitable to form the carbon layer 120. The concentration of the carbon in the carbon layer 120 can be suitably adjusted to obtain a desired etch selectivity and optical characteristics, such as light absorbance. The carbon layer 120 can have an etch selectivity higher than the etch selectivity of the resist layer 140 and the oxide layer 130. For example, the carbon concentration of the carbon layer 120 can be adjusted such that the ratio of the etching rate of the oxide layer 130 to the etching rate of the carbon layer 120 is about 1 to 10. The carbon layer 120 and the oxide layer 130 are used as hard masks for patterning the light blocking layer 110 in a subsequent process.

The oxide layer 130 can be formed through an oxidation process using oxygen as a source gas. More specifically, the oxide layer 130 can be formed by supplying an oxygen gas to a reaction chamber, and applying a suitable voltage to the reaction chamber. Although a natural oxide layer (not shown) can be formed on a top surface of the carbon layer 120, the oxidation process is additionally performed using oxygen as a source gas to grow the oxide layer 130 more stably, and to obtain a desired thickness of the oxide layer 130 without fail. For example, the thickness of the oxide layer 130 can be smaller than the thickness of the carbon layer 120 by 9 to 10 times.

Because the resist layer 140 is affected by the thickness of an underlayer (i.e., the oxide layer 130), the thickness of the resist layer 140 can be adjusted to be approximately equal to the thickness of the oxide layer 130. In addition, the thickness of the resist layer 140 may be properly selected in consideration of the thickness of the oxide layer 130 to prevent a resist layer pattern from being removed during a subsequent etch process for forming an oxide layer pattern.

Referring to FIG. 2, a resist layer pattern 141 is formed by exposure and development processes to selectively expose the oxide layer 130 (shown in FIG. 1). More specifically, the exposure process is performed on the resist layer 140 using an electronic beam (an e-beam), for example, to transfer a target pattern to the resist layer 140. Thereafter, portions of the resist layer 140, which are exposed to the e-beam or not exposed to the e-beam, are removed with a development agent. In this way, the resist layer pattern 141 is formed on the oxide layer 130 to selectively expose the oxide layer 130. The oxide layer 130 is selectively etched using the resist layer pattern 141 as an etch mask to form an oxide layer pattern 131. Because the resist layer pattern 141 used for patterning the oxide layer 130 is thin, the oxide layer pattern 131 can be finely formed. Therefore, the oxide layer pattern 131 can have a high resolution.

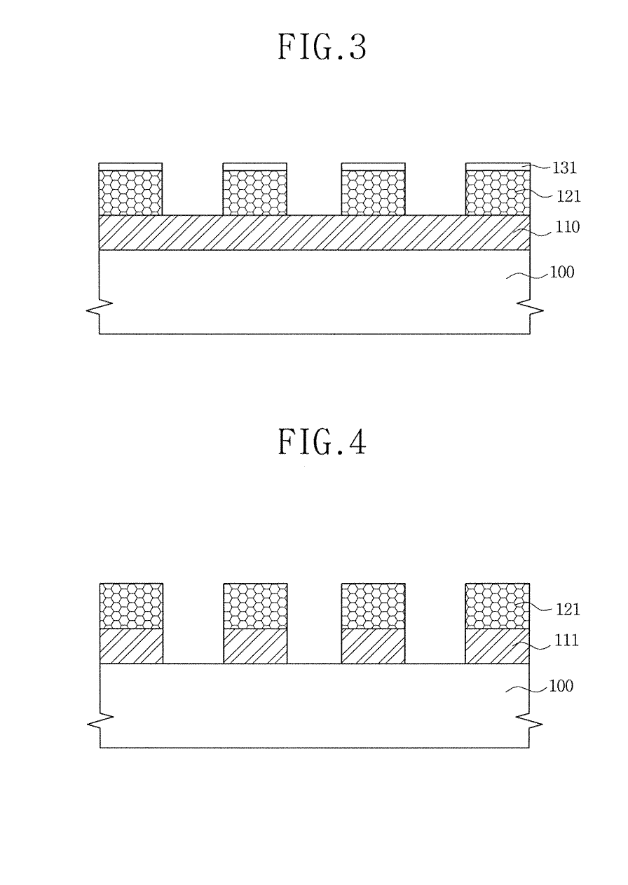

Referring to FIG. 3, the carbon layer 120 is etched using the oxide layer pattern 131 as an etch mask to form a carbon layer pattern 121. The resist layer pattern 141 is removed as a result of this etch process. The carbon layer pattern 121 can be formed, for example,through a dry etch process using oxygen plasma. Because the ratio of the etching rate of the oxide layer 130 (or the oxide layer pattern 131) to the etching rate of the carbon layer 120 is about 1 to 10, the thicker carbon layer 120 can be etched using the thinner oxide layer pattern 131 as an etch mask. The oxide layer pattern 131 and the carbon layer pattern 121 are used as hard masks in a subsequent etch process for patterning the light blocking layer 110.

Accordingly, the oxide layer pattern 131 having increased resolution is formed by patterning the thin oxide layer 130 using the thin resist layer pattern 141. Thereafter, the thicker carbon layer 120 can be patterned using the thinner oxide layer pattern 131, owing to the difference between the etch selectivities of the carbon layer 120 and the oxide layer pattern 131. Therefore, the oxide layer pattern 131 and the carbon layer pattern 121 can be used as hard masks having a sufficient thickness for patterning the light blocking layer 110 in a subsequent process.

Referring to FIG. 4, the light blocking layer 110 is etched, using the oxide layer pattern 131 (shown in FIG. 3) and the carbon layer pattern 121 as hard masks, to form a light blocking layer pattern 111. While portions of the light blocking layer 110 are etched away in the etch process, the carbon layer pattern 121 functions as a hard mask for preventing the light blocking layer pattern 111 from being damaged. Meanwhile, the oxide layer pattern 131 can be removed before the light blocking layer 110 is patterned. Alternatively, the oxide layer pattern 131 and the carbon layer pattern 121 can be used together as hard masks for patterning the light blocking layer 110, and then the oxide layer pattern 131 and the carbon layer pattern 121 can be removed.

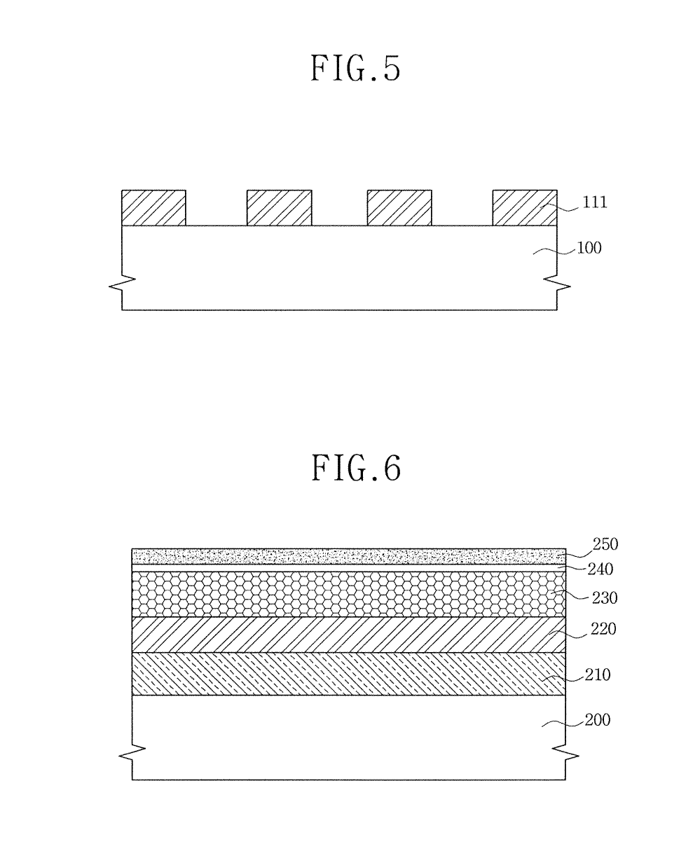

Referring to FIG. 5, the carbon layer pattern 121 (shown in FIG. 4) is removed. Thereafter, the transparent substrate 100 can be divided into a light shielding region covered with sections of the light blocking layer pattern 111 and a light transmitting region exposed through apertures of the light blocking layer pattern 111. The carbon layer pattern 121 can be removed using oxygen plasma, for example. In this case, the carbon layer pattern 121 (a hard mask) can be removed without damaging a top surface of the light blocking layer pattern 111 (an underlayer). Therefore, losses of the top surface of the light blocking layer pattern 111 can be prevented during the removal of the carbon layer pattern 121 (a hard mask).

FIGS. 6 through 12 illustrate an embodiment of a blank mask for a phase shift mask, and a method for fabricating a photomask using the blank mask. Referring to FIG. 6, a blank mask for a phase shift mask includes a phase shift layer 210, a light blocking layer 220, a carbon layer 230, and a first resist layer 250 are disposed on a transparent substrate 200, such as a quartz substrate. The phase shift layer 210 preferably comprises a material, such as molybdenum silicon oxide nitride (MoSiON), that can shift the phase of incident light. The light blocking layer 220 preferably comprises a material, such as chromium, that can block incident light. An oxide layer 240 can be disposed between the carbon layer 230 and the oxide layer 240. For example, the carbon layer 230 can be formed of amorphous carbon.

To fabricate a blank mask for a phase shift mask, the phase shift layer 210, the light blocking layer 220, the carbon layer 230, and the first resist layer 250 are formed on the transparent substrate 200. As stated above, the phase shift layer 210 can be formed of a material, such as molybdenum silicon oxide nitride, that can shift the phase of incident light, the light blocking layer 220 can be formed of a material, such as chromium, that can block incident light, and the oxide layer 240 can be disposed between the carbon layer 230 and the oxide layer 240.

As stated above, the carbon layer 230 can be formed of amorphous carbon. The carbon layer 230 can be formed using a compound including carbon as a reaction source. More specifically, after the transparent substrate 200 with the light blocking layer 220 formed thereon is loaded into a reaction chamber, a reaction source containing carbon can be supplied to the reaction chamber while applying a voltage to the reaction chamber suitable to form the carbon layer 230. The concentration of the carbon in the carbon layer 230 can be suitably adjusted to obtain a desired etch selectivity and optical characteristics, such as light absorbance. The carbon layer 230 can have an etch selectivity higher than the etch selectivity of the first resist layer 250 and the oxide layer 240. For example, the carbon concentration of the carbon layer 230 can be adjusted such that the ratio of the etching rate of the oxide layer 240 to the etching rate of the carbon layer 230 is about 1 to 10. The carbon layer 230 and the oxide layer 240 are used as hard masks for patterning the light blocking layer 220 and the light blocking layer 210 in a subsequent process.

The oxide layer 240 can be formed through an oxidation process using oxygen as a source gas. More specifically, the oxide layer 240 can be formed by supplying an oxygen gas to a reaction chamber, and applying a suitable voltage to the reaction chamber. Although a natural oxide layer (not shown) can be formed on a top surface of the carbon layer 230, the oxidation process is additionally performed using oxygen as a source gas to grow the oxide layer 240 more stably, and to obtain a desired thickness of the oxide layer 240 without fail. For example, the thickness of the oxide layer 240 can be smaller than the thickness of the carbon layer 230 by 9 to 10 times.

Because the first resist layer 250 is affected by the thickness of an underlayer (i.e., the oxide layer 240), the thickness of the first resist layer 250 can be adjusted to be approximately equal to the thickness of the oxide layer 240. In addition, the thickness of the first resist layer 250 may be properly selected in consideration of the thickness of the oxide layer 240 to prevent a resist layer pattern from being removed during a subsequent etch process for forming an oxide layer pattern.

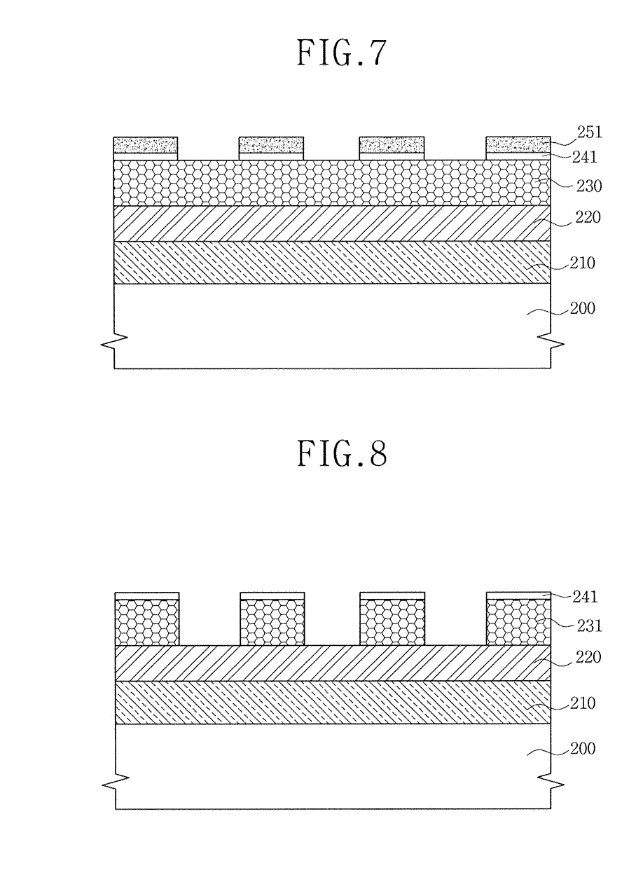

Referring to FIG. 7, a resist layer pattern 251 is formed by exposure and development processes to selectively expose the oxide layer 240 (shown in FIG. 6). More specifically, the exposure process is performed on the first resist layer 250 using an electronic beam (an e-beam), for example, to transfer a target pattern to the first resist layer 250. Thereafter, portions of the first resist layer 250, which are exposed to the e-beam or not exposed to the e-beam, are removed with a development agent. In this way, the resist layer pattern 251 is formed on the oxide layer 240 to selectively expose the oxide layer 240. The oxide layer 240 is selectively etched using the resist layer pattern 251 as an etch mask to form an oxide layer pattern 241. Because the resist layer pattern 251 used for patterning the oxide layer 240 is thin, the oxide layer pattern 241 can be finely formed. Therefore, the oxide layer pattern 241 can have a high resolution.

Referring to FIG. 8, the carbon layer 230 is etched, using the oxide layer pattern 241 as an etch mask, to form a carbon layer pattern 231. The resist layer pattern 251 is removed as a result of this etch process. The carbon layer pattern 231 can be formed, for example, through a dry etch process using oxygen plasma. Because the ratio of the etching rate of the oxide layer 240 (or the oxide layer pattern 241) to the etching rate of the carbon layer 230 is about 1 to 10, the thicker carbon layer 230 can be etched using the thinner oxide layer pattern 241 as an etch mask. The oxide layer pattern 241 and the carbon layer pattern 231 are used as hard masks in a subsequent etch process for patterning the light blocking layer 220.

Accordingly, the oxide layer pattern 241 having increased resolution is formed by patterning the thin oxide layer 240 using the thin resist layer pattern 251. Thereafter, the thicker carbon layer 230 can be patterned using the thinner oxide layer pattern 241, owing to the difference between the etch selectivities of the carbon layer 230 and the oxide layer pattern 241. Therefore, the oxide layer pattern 241 and the carbon layer pattern 231 can be used as hard masks having a sufficient thickness for patterning the light blocking layer 220 and the phase shift layer 210 in a subsequent process.

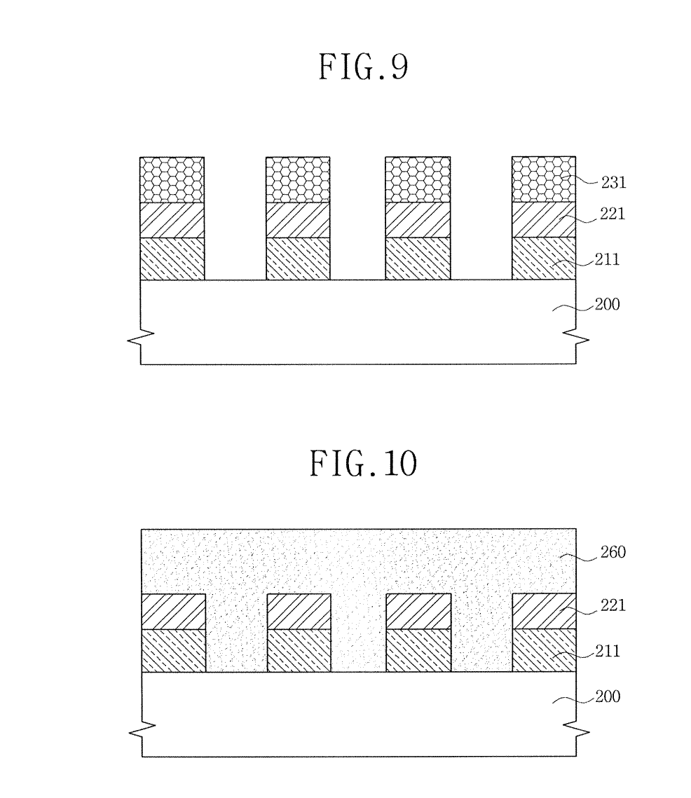

Referring to FIG. 9, the light blocking layer 220 and the phase shift layer 220 are etched, using the carbon layer pattern 231 as a hard mask, and patterned to form a light blocking layer pattern 221 and a phase shift layer pattern 211. The light blocking layer pattern 221 and the phase shift layer pattern 211 can be formed through a dry or wet etch process. While portions of the light blocking layer 220 and the phase shift layer 210 are etched away in the etch process, the carbon layer pattern 231 functions as a hard mask for preventing the light blocking layer pattern 221 and the phase shift layer pattern 211 from being damaged.

Meanwhile, the oxide layer pattern 241 (shown in FIG. 8) can be removed before the light blocking layer 220 and the phase shift layer 210 are patterned. Alternatively, the oxide layer pattern 241 and the carbon layer pattern 231 can be used together as hard masks for patterning the light blocking layer 220 and the phase shift layer 210, and then the oxide layer pattern 241 and the carbon layer pattern 231 can be removed.

Referring to FIG. 10, the carbon layer pattern 231 (shown in FIG. 9) is removed. Thereafter, a second resist layer 260 is formed on the transparent substrate 200 where the phase shift layer pattern 211 and the light blocking layer pattern 221 are formed. The carbon layer pattern 231 can be removed through a dry etch process using oxygen plasma, for example. In this case, the carbon layer pattern 231 (a hard mask) can be removed without damaging a top surface of the light blocking layer pattern 221 (an underlayer). Therefore, losses of the top surface of the light blocking layer pattern 221 can be prevented during the removal of the carbon layer pattern 231 (a hard mask).

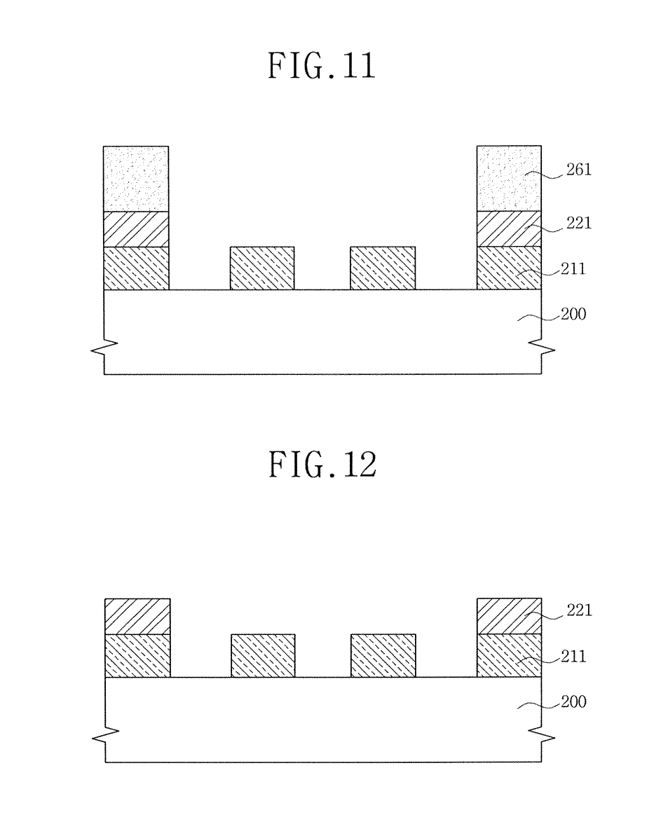

Referring to FIG. 11, a second resist layer pattern 261 is formed by patterning the second resist layer 260 through exposure and development processes so as to selectively expose the transparent substrate 200. The second resist layer pattern 261 can be at an edge region such as a frame region to block unnecessary light in a subsequent wafer processing process.

Referring to FIG. 12, the light blocking layer pattern 221 exposed through an opening of the second resist layer pattern 261 (refer to FIG. 11) is selectively etched. Therefore, both the phase shift layer pattern 211 and the light blocking layer pattern 221 can be formed at a region (e.g., a frame region) of the transparent substrate 200, and only the phase shift layer pattern 211 can be formed at another region (e.g., a main chip region for shifting the phase of incident light) of the transparent substrate 200.

Although preferred embodiments of the invention have been disclosed for illustrative purposes, those skilled in the art will appreciate that various modifications, additions and substitutions are possible, without departing from the scope and spirit of the invention as defined in the accompanying claims.

What is claimed is:

1. A blank mask comprising an etch target layer, a resist layer, and a carbon layer disposed between the etch target and resist layers.

2. The blank mask of claim 1, wherein the etch target layer is a light blocking layer.

3. The blank mask of claim 1, wherein the etch target layer comprises a phase shift layer and a light blocking layer.

4. The blank mask of claim 1 further comprising an oxide layer disposed between the carbon and resist layers.

5. The blank mask of claim 4, wherein a ratio of an etching rate of the oxide layer to an etching rate of the carbon layer is about one to ten.

6. The blank mask of claim 4, wherein the oxide layer is about nine to ten time as thin as the carbon layer.

7. A method for fabricating a photomask, the method comprising:
forming a light blocking layer and a carbon layer on a transparent substrate;
forming a carbon layer pattern by selectively etching the carbon layer through a first etch process using a resist layer pattern that selectively exposes the carbon layer;
etching the light blocking layer through a second etch process, using the carbon layer pattern as a hard mask, to form a light blocking layer pattern; and,
removing the carbon layer pattern.

8. The method of claim 7, wherein the light blocking layer comprises chromium.

9. The method of claim 7 further comprising forming an oxide layer on the carbon layer.

10. The method of claim 9, wherein a ratio of an etching rate of the oxide layer to an etching rate of the carbon layer is about one to ten.

11. The method of claim 7, wherein the first etch process is a dry etch process using oxygen plasma.

12. The method of claim 7, wherein the second etch process is a dry or wet etch process.

13. The method of claim 7, wherein the removing of the carbon layer pattern is performed using oxygen plasma.

14. A method for fabricating a photomask, the method comprising:
forming a phase shift layer, a light blocking layer, and a carbon layer on a transparent substrate;
selectively etching the carbon layer through a first etch process, using a first resist layer pattern capable of selectively exposing the carbon layer, to form a carbon layer pattern;
selectively etching the light blocking layer and the phase shift layer through a second etch process, using the carbon layer pattern as a hard mask, to form a light blocking layer pattern and a phase shift layer pattern;
removing the carbon layer pattern;
forming a second resist layer pattern capable of selectively exposing the transparent substrate on which the light blocking layer pattern and the phase shift layer pattern are formed;
etching the light blocking layer pattern exposed by the second resist layer pattern; and,
removing the second resist layer pattern.

15. The method of claim 14, wherein the phase shift layer comprises molybdenum silicon oxide nitride, and the light blocking layer comprises chromium.

16. The method of claim 14 further comprising forming an oxide layer on the carbon layer.

17. The method of claim 16, wherein a ratio of an etching rate of the oxide layer to an etching rate of the carbon layer is about one to ten.

18. The method of claim 14, wherein the first etch process is a dry etch process using oxygen plasma.

19. The method of claim 14, wherein the second etch process is a dry or wet etch process.

20. The method of claim 14, wherein the removing of the carbon layer pattern is performed using oxygen plasma.
